(19) United States
(12) Patent Application Publication
(10) Pub. No.: US 2006/0189045 A1
(43) Pub. Date: Aug. 24, 2006

(54) Method for fabricating a sublithographic contact structure in a memory cell

(76) Inventors: Danny Pak-Chum Shum, Poughkeepsie, NY (US); Armin Tilke, Beacon, NY (US)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/331,771

(22) Filed: Jan. 13, 2006

(30) Foreign Application Priority Data
Jan. 14, 2005 (DE) 10 2005 001 902.1

(51) Int. Cl. H01L 21/339

(52) U.S. Cl. 438/148

(57) ABSTRACT

A method for fabricating a sublithographic contact structure in a memory cell in a semiconductor component is disclosed. In one embodiment, the method includes forming a trench structure having first spacers on walls of the trench structure, a first sublithographic dimension being formed in a region between the first spacers situated on mutually opposite walls in at least one direction parallel to a wafer surface. The insulator layer is etched in a region between the first spacers situated on mutually opposite walls for forming a first passage hole, the first spacers being used as an etching mask. A layer made of an electrically conductive material is deposited at least over the first passage hole and partially etching back the layer made of the electrically conductive material in the first passage hole forming a first contact electrode. A layer made of a resistance change material is deposited over the first passage hole and partially etching back the resistance change material in the first passage hole forming a resistance change material zone.

### CROSS-REFERENCE TO RELATED APPLICATIONS

This Utility Patent Application claims priority to German Patent Application No. DE 10 2005 001 902.1, filed on Jan. 14, 2005, which is incorporated herein by reference.

### FIELD OF THE INVENTION

The present invention lies in the technical field of semiconductor components and relates in particular to a method for fabricating a sublithographic contact structure in a memory cell.

### BACKGROUND

Phase change materials are regarded by experts as a basic material for a new, promising type of nonvolatile memory cells. Phase change materials can be brought—by heating—to different phase states which differ from one another in terms of their optical properties (in particular reflectivity) and electrical properties (in particular electrical resistance). The different phase states can be assigned different logic values, so that information items can be stored in memory cells based on phase change materials by supplying heat and can be read out again whilst utilizing the optical or electrical properties.

Suitable phase change materials are, in particular, chalcogenides, that is to say alloys containing at least one element from main group VI (chalcogenes) of the periodic table. With regard to the electrical properties, chalcogenides are advantageously distinguished in particular by the fact that their electrical resistance changes by a number of orders of magnitude if a change in the phase state between the amorphous phase and the crystalline phase is induced.

In memory cells based on phase change materials (called phase change memory cells or PC memory cells hereinafter), it is practical for a phase change to be induced by an electrical heating pulse (Joule heat). If the phase change material of the memory cell is in a high-resistance amorphous state, then it can be converted into a low-resistance crystalline state if a heating pulse heats the material above the crystallization temperature thereof and causes it to crystallize in the process. This operation is generally referred to as “writing to” (or “programming”) the memory cell. The reverse operation, in which the phase change material of the memory cell is converted from the low-resistance crystalline state to the high-resistance amorphous state, is realized by heating the phase change material beyond the melting point and subsequently quenching it by rapid cooling into the amorphous state. This is generally referred to as “erasing” the memory cell.

A typical construction of a PC memory cell of the bottom contact type is shown schematically in FIGS. 1A and 1B. Accordingly, a layer made of a polycrystalline chalcogenide 1 is arranged between a bottom electrode 2 and a top electrode 3. The bottom electrode 2 is embodied as a heating electrode having a higher electrical resistance than the chalcogenide layer 1. If a sufficiently large current flows through the bottom or heating electrode 2, then the Joule heat generated in the heating electrode 2 effects a phase transition in the chalcogenide layer 1 adjoining the latter, namely in the programmable, that is to say writeable and erasable volume 4. If the temperature in the programmable volume 4 exceeds the melting point of the chalcogenide and if the programmable volume 4 is caused to cool down sufficiently rapidly, then a transition from the crystalline state to the amorphous state is induced (see FIG. 1B). The following conversely holds true: if the temperature of the programmable volume 4 exceeds the crystallization temperature of the chalcogenide, then a phase transition from the amorphous state to the crystalline state is induced (see FIG. 1A).

As has already been explained further above, the phase state of a memory cell can be read out electrically, inter alia, a read voltage being applied to the memory cell. In order to ensure that the read voltage does not effect unintentional reprogramming of the memory cell, the current I_{read} through the memory cell which results from the read voltage must be significantly smaller than the programming current Iₛₑₜ or erase current Iᵣₑₛₑₜ. The following relationship I_{read}<<Iₛₑₜ<Iᵣₑₛₑₜ holds true in this case.

One essential disadvantage of such PC memory cells resides in the fact that relatively high currents have to be applied for the write operation, and in particular for the erase operation, in order to heat the phase change medium beyond the crystallization temperature and, respectively, the melting point.

In order to solve this problem, it has primarily been attempted hitherto to reduce the volume to be programmed by means of reducing the contact area between the electrodes and the phase change material, since the currents required for writing and erasure generally scale with the volume to be programmed. However, limits are imposed on this undertaking by the minimum dimensions that can be achieved photolithographically. With the optical (UV)-lithographic techniques available at the present time, it is possible, as is known to the person skilled in the art, to achieve a minimum lithographic dimension (F) of only approximately 50 nm. However, much smaller minimum dimensions would be desirable for reducing the maximum current for writing to or erasing the memory cells.

### SUMMARY

The present invention provides a method for fabricating a sublithographic contact structure in a memory cell in a semiconductor component. In one embodiment, the method includes forming a trench structure having first spacers on walls of the trench structure, a first sublithographic dimension being formed in a region between the first spacers situated on mutually opposite walls in at least one direction parallel to a wafer surface. The insulator layer is etched in a region between the first spacers situated on mutually opposite walls for forming a first passage hole, the first spacers being used as an etching mask. A layer made of an electrically conductive material is deposited at least over the first passage hole and partially etching back the layer made of the electrically conductive material in the first passage hole forming a first contact electrode. A layer made of a resistance change material is deposited over the first passage hole and partially etching back the resistance change material in the first passage hole forming a resistance change material zone.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A and 1B schematically illustrate conventional resistance change memory cells.

FIGS. 2A to 2E schematically illustrate a first embodiment of the method according to the invention for fabricating a sublithographic contact structure.

FIGS. 3A to 3C schematically illustrate an anisotropic etching method.

FIGS. 4A to 4E schematically illustrate a second embodiment of the method according to the invention for fabricating a sublithographic contact structure.

FIG. 5 schematically illustrates a variant with respect to the second embodiment of the method according to the invention in FIGS. 4A to 4E.

FIGS. 6A to 6F schematically illustrate a further variant with respect to the second embodiment of the method according to the invention in FIGS. 4A to 4E.

FIGS. 7A to 7E schematically illustrate an embodiment of the method according to the invention for simultaneously fabricating a plurality of sublithographic contact structures.

FIGS. 8A and 8B schematically illustrate a plan view in the method according to the invention in FIGS. 7A to 7E.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a method for fabricating a sublithographic contact structure by means of which it is possible to realize a memory cell which can be switched between two states having a mutually different electrical resistance using comparatively small electric currents. With regard to mass production of such memory components, a method of this type is intended to be able to be carried out simply and cost-effectively.

According to one embodiment, the invention provides a method for fabricating a sublithographic contact structure of a resistance change material memory cell having a resistance change material and first and second contact electrodes adjoining the resistance change material.

The method includes providing a semiconductor wafer processed by front-end-of-line (FEOL) processing known to a person skilled in the art. In this case, the semiconductor wafer has at least one electrical connecting contact (e.g. “plug”) connected to an active structure (e.g., transistor, in particular MOS field effect transistor) on one of its two opposite surfaces parallel to one another. The connecting contact may be produced in a conventional manner for example from W, TiW, TiSiN, TaSiN or TiAlN. Hereinafter, “the wafer surface” always means that surface of the semiconductor wafer which is provided with the connecting contact.

Afterward, a first insulator layer made of a first insulating, dielectric material is deposited on the wafer surface at least over the connecting contact. Although further insulating layers may be present in the semiconductor component, here the expression “first insulator layer” means that layer made of an insulating, dielectric material which is deposited on the semiconductor wafer at least over the electrical connecting contact thereof. The insulator layer may comprise SiO₂ or SiN, by way of example.

A trench structure is thereupon formed in the first insulator layer, trench structure being equipped with a bottom that is preferably essentially parallel to the wafer surface and walls that are essentially perpendicular to the wafer surface. In this case, the trench structure is positioned at least partially over the electrical connecting contact.

In a first embodiment of the method according to the invention, the trench structure may be formed such that firstly an etching stop layer, e.g. comprising SiN, is deposited on the first insulator layer, and it is subsequently patterned by application of conventional exposure technology for the purpose of forming an etching mask. Afterward, the first insulator layer is partially etched with the aid of the etching mask for the purpose of forming a trench structure.

As an alternative to this, in a second embodiment of the method according to the invention, the trench structure may be formed in such a way that firstly an etching stop layer is deposited on the first insulator layer and it is patterned in a conventional manner for the purpose of forming an etching mask. The first insulator layer is then etched as far as the connecting contact with the aid of the etching mask for the purpose of forming a passage hole, a second insulator layer made of a second dielectric material, which is different from the first dielectric material, thereupon being deposited at least over the passage hole and being partially etched back in the passage hole for the purpose of forming a trench structure. The second embodiment of the method according to the invention has an advantage over its first embodiment that the properties of the second dielectric can be chosen in a desired manner, to be precise independently of the properties of the first dielectric. According to the invention, it is preferred, for example, to choose the thermal conductivity of the second dielectric material to be lower than the thermal conductivity of the first dielectric material, so that, in a particularly advantageous manner, the sublithographic contact structure formed within the second dielectric can be provided with surroundings that inhibit the dissipation of heat. This measure contributes appreciably to reducing the power loss and lowering the maximum current consumption.

Irrespective of which of the above embodiments was carried out, in the method according to the invention a first layer made of a spacer material is thereupon deposited at least over the trench structure. In this case, the spacer material is to be chosen such that it can fulfill a function as an etching stop layer. Accordingly, the spacer material may comprise SiN, by way of example. The layer made of the spacer material is subsequently etched back anisotropically as far as the bottom of the trench structure in a direction essentially perpendicular to the wafer surface, the anisotropic etching-back of the spacer material layer having the effect that first spacers remain on the walls of the trench structure, as is explained in more detail further below. In this case, the thickness or lateral dimension, that is to say dimension of the spacer layer material in a direction parallel to the wafer surface, is chosen such that a first sublithographic dimension is formed in a region between the first spacers situated on mutually opposite walls in at least one direction parallel to the wafer surface. In other words, there is at least one distance between the first spacers on mutually opposite walls of the trench structure which has a sublithographic dimension.

As a further process, the insulator layer is etched at least in the region between the first spacers situated on mutually opposite walls as far as the connecting contact for the purpose of forming a first passage hole, the first spacers being used as an etching mask.

A layer made of an electrically conductive material is then deposited at least over the first passage hole and partially etched back in the first passage hole in order thereby to form a first contact electrode.

In this embodiment, the first contact electrode is preferably configured in the form of a heating electrode, that is to say includes an electrically conductive material having a higher electrical resistance than the resistance change material that is in an electrical contact therewith.

In order to fabricate the sublithographic contact structure, in one method according to the invention, a layer made of a resistance change material is furthermore deposited at least over the trench structure and is partially etched back in the first passage hole for the purpose of forming a resistance change material zone. Afterward, a layer made of an electrically conductive material is deposited at least on the resistance change material zone for the purpose of forming a second electrode. Usually, the layer made of an electrically conductive material is additionally removed outside the trench structure, which may be effected by means of chemical mechanical polishing, by way of example.

The method according to the invention makes it possible to fabricate a sublithographic contact structure in a resistance change material memory cell by using the spacers on the trench structure walls as an etching mask to form a first passage hole having at least one sublithographic dimension in a direction parallel to the wafer surface, in which the sublithographic contact structure is then formed by depositing and etching back the different layers in stack form. In this way, a contact area is produced between the first contact electrode and the resistance change material, and a contact area is produced between the second contact electrode and the resistance change material, with at least one sublithographic dimension in a direction parallel to the wafer surface.

In accordance with a embodiment of the two above embodiments of the method according to the invention, after depositing the layer made of an electrically conductive material and partially etching back this layer in the first passage hole for the purpose of forming the first contact electrode, a layer made of a resistance change material is deposited at least over the passage hole and afterward both the first spacers and the resistance change material situated between the latter in the trench structure are removed, for example by etching. Afterward, a second layer made of a spacer material, which is intended to serve as an etching mask and may accordingly comprise SiN, by way of example, is deposited at least over the trench structure and etched back anisotropically until the resistance change material is uncovered in a direction essentially perpendicular to the wafer surface, spacer layer material remaining on the walls of the trench structure, said material forming second spacers which form a second sublithographic dimension in at least one direction parallel to the wafer surface. In this embodiment, the second sublithographic dimension is advantageously different from the first sublithographic dimension, which can be achieved in a simple manner by choosing the layer thickness of the second deposited spacer material layer to be different from the layer thickness of the first deposited spacer material layer. Furthermore, a layer made of an electrically conductive material is deposited on the resistance change material for the purpose of forming a second contact electrode on the trench structure, which material is usually removed outside the trench structure by chemical mechanical polishing, by way of example. The deposition and etching-back of the second spacer material layer has the advantageous effect that the size of the contact area between the second contact electrode and the resistance change material can be formed independently of the size of the contact area between the first contact electrode and the resistance change material and can thus be adapted to different requirements in a desired manner. Thus, the second sublithographic dimension may for example and preferably be smaller than the first sublithographic dimension, so that the contact area between the second contact electrode and the resistance change material is smaller than the contact area between the first contact electrode and the resistance change material.

In accordance with a further particularly advantageous variant of the method according to the invention, after depositing the layer made of an electrically conductive material on the resistance change material for the purpose of forming the second contact electrode, firstly the first and second spacers and the electrically conductive material situated between the latter are partially etched back. Afterward, in a direction essentially parallel to the wafer surface, the spacers on the walls of the trench structure are partially etched back isotropically (e.g. by wet-chemical etching) for the purpose of increasing the distance between the spacers situated on opposite walls in a direction parallel to the wafer surface. In other words, the partial isotropic etching-back effects a partial removal of the spacers from the trench structure walls, thereby enlarging the region between the spacers situated on opposite walls of the trench structure, thereby partially uncovering the surface of the second dielectric in the trench structure from above. A selective isotropic etching of the second dielectric material is subsequently carried out, which may be effected wet-chemically, by way of example. In this case, the etching attack takes place on the partially uncovered surface of the second dielectric material, the second dielectric material advantageously and preferably being completely removed. In other words, the selective removal of the second dielectric material uncovers the sublithographic contact structure constructed from a layer stack, a gap arising between the layer stack of the sublithographic contact structure, in particular the second contact electrode, and the spacer material. A third insulator layer made of a third dielectric material is then deposited conformally at least in the region of the trench structure, which has the effect that the region laterally with respect to the layer stack of the sublithographic contact structure is filled with the third dielectric material until the gap between the layer stack of the sublithographic contact structure and the spacer material has grown over. Once the gap has grown over, the deposited third dielectric material thereupon grows only above the layer stack. The final step involves additionally forming an electrically conductive connection to the second contact electrode in the third insulator layer. Since, in this variant of the second embodiment of the method according to the invention, the original volume of the second dielectric material which has been partially or completely etched away is no longer completely filled with the third dielectric material, so that an enclosed cavity arises, it is possible, in an extremely advantageous manner, to produce an excellent thermal insulation of the sublithographic contact structure on account of the cavity structure. In this way, the power loss of the memory cell can be significantly reduced and the maximum current for switching and erasing the memory cell can be lowered in a desired manner.

According to the invention, it may furthermore be advantageous if the trench structure has at least one minimum dimension that can be achieved photolithographically in at least one direction.

In accordance with a further embodiment, the invention provides a method for fabricating sublithographic contact structures in memory cells in a semiconductor component, in which firstly provision is made of a front-end-of-line (FEOL) finished processed semiconductor wafer with at least two electrical connecting contacts each connected to an active structure on one of its two opposite surfaces. An insulator layer made of a dielectric material is thereupon deposited on the semiconductor wafer at least partially over the connecting contacts, followed by formation of an etching mask on the insulator layer and etching of the dielectric as far as the first connecting contacts for the purpose of forming a first passage hole. A layer made of an electrically conductive material is then deposited and partially etched back in order to form a first contact electrode. Furthermore, a layer made of a resistance change material is deposited and partially etched back in the first passage hole. Next, a layer made of an electrically conductive material is deposited and partially etched back in the first passage hole for the purpose of forming a second contact electrode. A layer made of a spacer material is then deposited, which layer is intended to serve as an etching mask and may accordingly comprise SiN, by way of example, and is subsequently etched back anisotropically in the passage hole until the resistance change material is uncovered, spacer layer material remaining on the walls of the passage hole, and first spacers being formed which have a sublithographic dimension in at least one direction parallel to the wafer surface. Afterward, the second contact electrode, the resistance change material zone and the first contact electrode (stack comprising the two contact electrodes and the resistance change material) are etched as far as the connecting contacts, the spacer layer material being used as an etching mask.

Embodiments of the method according to the invention advantageously makes it possible to simultaneously form a plurality of sublithographic contact structures by virtue of the spacers with a sublithographic distance in a direction parallel to the wafer surface serving as an etching mask and the layer sequence below the spacer layer material producing the sublithographic contact structure. In this case, it may be advantageous if the first passage hole has at least one minimum dimension that can be achieved photolithographically in at least one direction.

According to the invention, the expression “sublithographic dimension” as is used here means a linear dimension which is smaller than the dimension that can be achieved with the optical (UV)-lithographic methods, which at the present time is approximately 50 nm. However, this expression is intended generally to encompass all linear dimensions which are smaller than the achievable minimum feature size (usually abbreviated to “F”) which can be fabricated by means of the technology used.

Resistance change material in the sense of the present invention is to be understood to be any material which is suitable for assuming at least two states having mutually different resistance values in response to selected (determinable) energy pulses, for example electrical heating pulses. The at least two states having a different electrical resistance can in this case be assigned to different structural phase states, such as an amorphous phase state or a crystalline phase state, so that switching between the states having a different electrical resistance is accompanied by a change in the phase state. In principle, however, it is also possible that the at least two states having a different electrical resistance may be different within a single phase state. Typical materials which are suitable and preferred as resistance change material for use in the method according to the invention are phase change materials, such as, in particular, chalcogenide alloys.

The first contact electrode and/or the second contact electrode of the memory cell may generally be produced from a suitable electrode material known to the person skilled in the art, which electrode material is for example W, TiN, Ta, TaN, TiW, TiSiN, TaSiN, TiON and TiAIN. The insulator layer is advantageously produced from an insulating dielectric material, for example SiO₂, SiN or a so-called low-K material (material having a low dielectric constant).

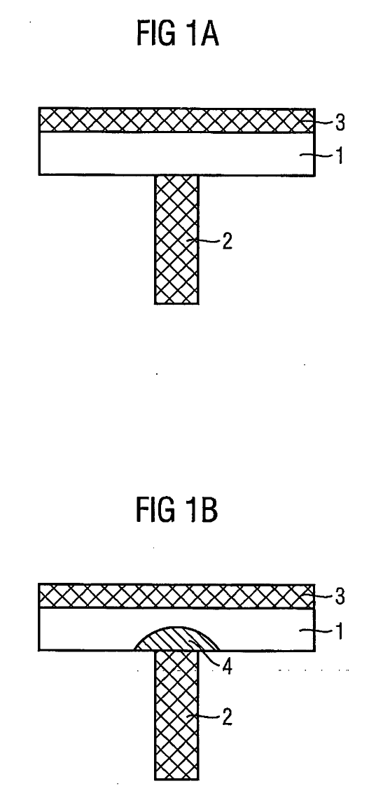

FIGS. 1A and 1B, which illustrate two PC memory cells known in the prior art, have already been described in the introduction, so that a further description can be dispensed with here.

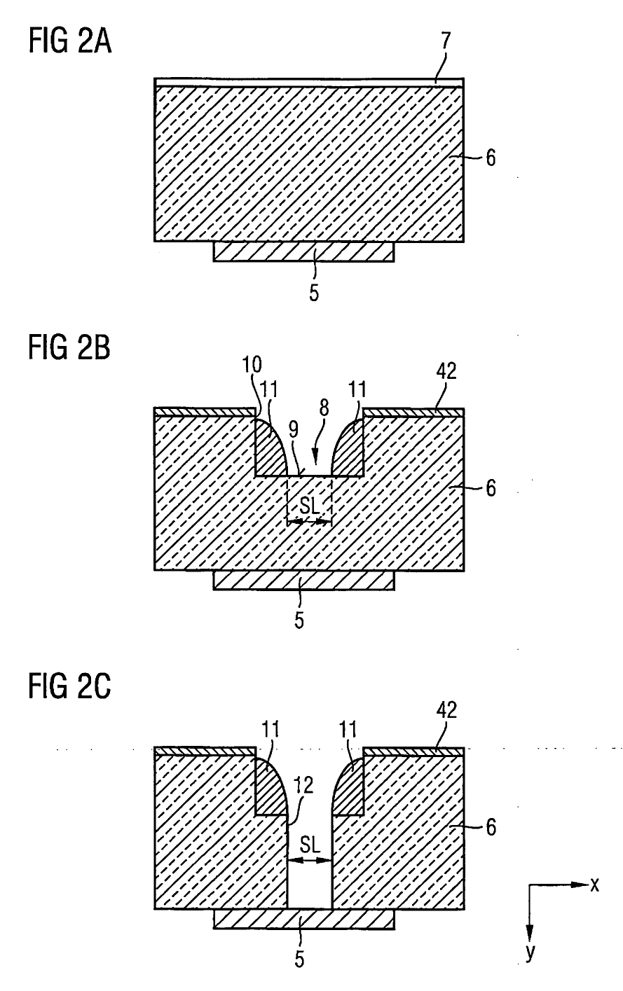

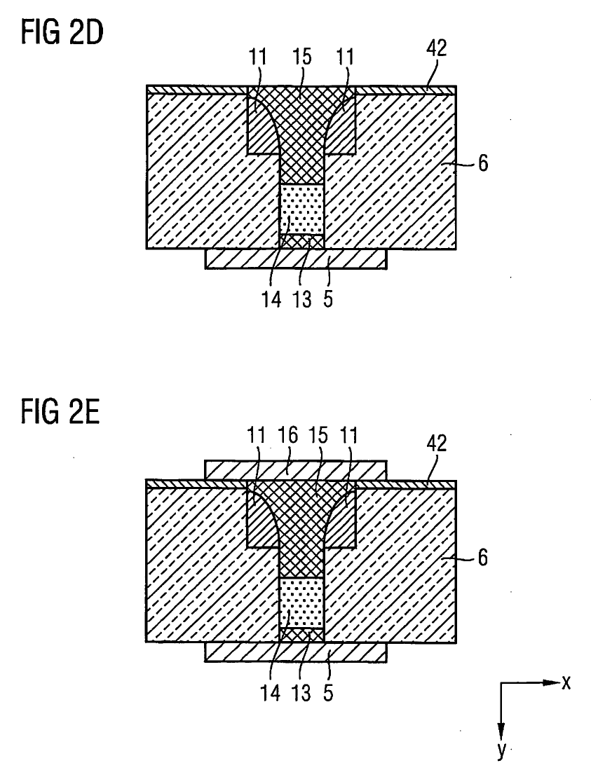

Firstly, the sequence of FIGS. 2A to 2E shall be considered, which schematically illustrate a first embodiment of the method according to the invention for fabricating a sublithographic contact structure.

A first insulator layer 6 made of a first insulating dielectric material, for example SiO₂, is firstly deposited on the surface of a semiconductor wafer (not specifically illustrated) at least over a connecting contact 5 connected to an active structure of the semiconductor wafer. An etching stop layer 7 made of SiN, for example, is then deposited on the first insulator layer 6 (FIG. 2A). A trench structure 8 is thereupon formed in the first insulator layer 6 over the connecting contact 5, said trench structure being equipped with a bottom 9 essentially parallel to the wafer surface and walls 10 essentially perpendicular to the wafer surface. In this embodiment, the trench structure is fabricated by a customary patterning of the etching stop layer 7 for the purpose of forming an etching mask 42 and an isotropic etching of the first dielectric layer 6. A first layer (not specifically illustrated) made of a spacer material is then deposited at least over the trench structure. The spacer material comprises SiN, by way of example. The layer made of the spacer material is subsequently etched back anisotropically as far as the bottom of the trench structure in a direction y perpendicular to the wafer surface, first spacers 11 remaining on the walls of the trench structure. In this embodiment, the lateral dimension of the spacers 11 in a direction x parallel to the wafer surface is chosen such that a first sublithographic dimension SL is formed in a region between the first spacers situated on mutually opposite walls in at least one direction x parallel to the wafer surface (FIG. 2B). The first insulator layer 6 is then etched using the first spacers 11 as far as the connecting contact 5 for the purpose of forming a first passage hole 12 having a form that is for example rectangular or for example round in plan view, which passage hole, for its part, has at least one sublithographic dimension SL in at least one direction (FIG. 2C). A layer (not specifically illustrated) made of an electrically conductive material is thereupon deposited at least over the first passage hole and partially etched back in the first passage hole in order thereby to form a first contact electrode 13. In this embodiment, the material of the first contact electrode 13 is chosen such that the latter acts as a heating electrode. A layer (not specifically illustrated) made of a resistance change material is then deposited at least over the trench structure and is partially etched back in the first passage hole, so that a resistance change material zone 14 remains above the heating electrode 13. Afterward, a layer (not specifically illustrated) made of an electrically conductive material is deposited at least on the resistance change material for the purpose of forming a second contact electrode 15 and is removed outside the trench structure 8 by chemical mechanical polishing (FIG. 2D). Finally, a further connecting contact 16 made of an electrically conductive material is formed on the second contact electrode 15 (FIG. 2E).

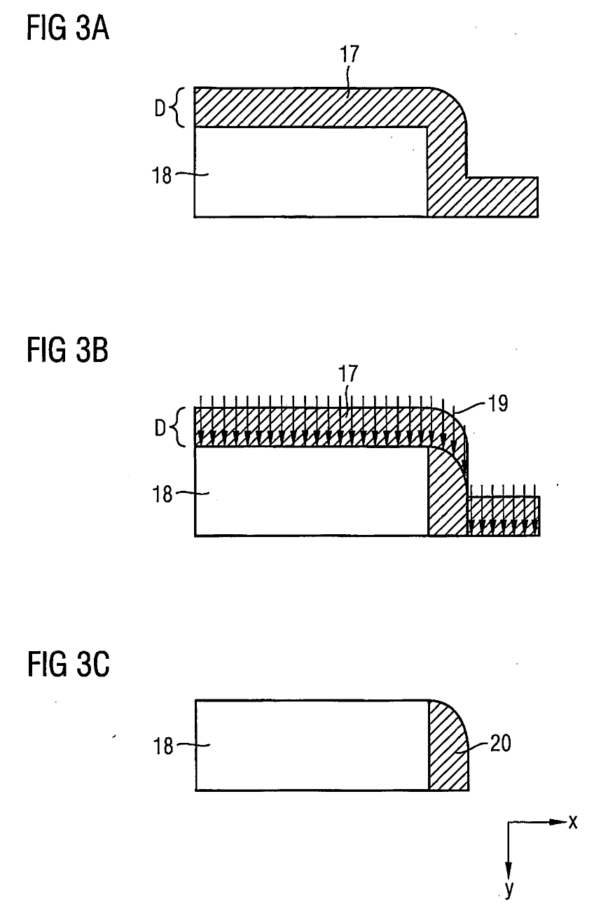

The anisotropic etching method used in the method according to the invention will now be described schematically with reference to the sequence of FIGS. 3A to 3C. FIG. 3A shows the situation in which a layer 17 made of a spacer material has been deposited conformally over a step 18. If an anisotropic etch is effected for example by means of RIE (reactive ion etching), represented by the arrows 19 pointing from top to bottom (FIG. 3B), then a uniform removal of material is effected over the step in a direction y, which has the effect that spacer material 20 remains on the step (FIG. 3C). In this case, the lateral dimension in direction x of the spacer layer material 20 remaining on the trench structure walls during the anisotropic etching-back can be set by way of the thickness D of the deposited layer 17 made of spacer material. In this case, it generally holds true that the thicker this layer 17, the larger the lateral dimension in direction x of the spacer layer material 20 remaining on the trench structure walls. With regard to the method according to the invention, this means that with a thicker spacer material layer during otherwise unchanged anisotropic etching-back, it is possible to realize a smaller sublithographic dimension between the spacer layer material remaining on mutually opposite trench structure walls.

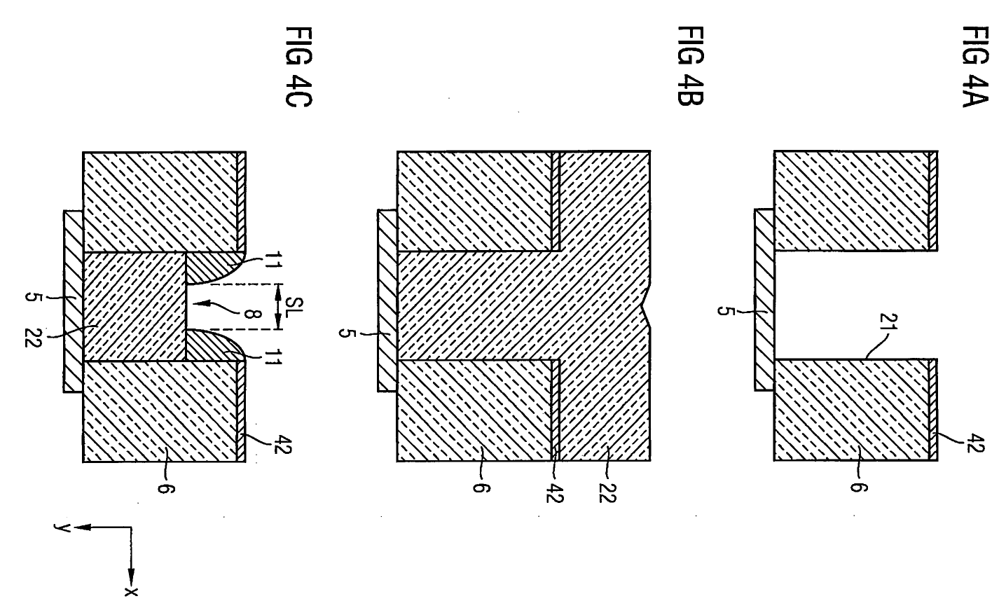

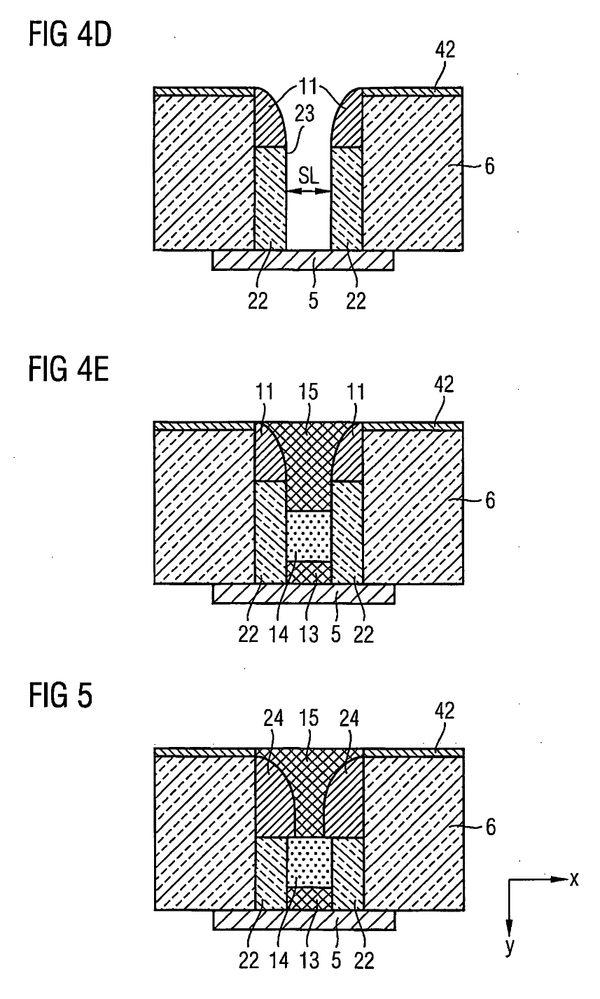

Reference shall now be made to the sequence of FIGS. 4A to 4E, which schematically illustrate a second embodiment of the method according to the invention for fabricating a sublithographic contact structure.

In the second embodiment of the method according to the invention, firstly a first insulator layer 6 made of a first insulating dielectric material, for example SiO₂, is deposited on the surface of a semiconductor wafer (not specifically illustrated) at least over a connecting contact 5 connected to an active structure of the semiconductor wafer. An etching stop layer 7 made of SiN, by way of example, is then deposited on the first insulator layer 6, and is patterned in a known manner for the purpose of forming an etching mask 42. A first passage hole 21 having a form that is for example rectangular or a form that is for example round in plan view is thereupon etched in the first insulator layer 6 over the connecting contact 5 (FIG. 4A). A second insulator layer 22 made of a second dielectric material, which is different from the first dielectric material, is then deposited at least over the first passage hole 21 (FIG. 4B) and is partially etched back in the first passage hole 21 for the purpose of forming a trench structure 8. A first layer (not specifically illustrated) made of a spacer material, for example SiN, is then deposited at least over the trench structure 8 and is subsequently etched back anisotropically as far as the bottom of the trench structure 8 in a direction y perpendicular to the wafer surface, first spacers 11 remaining on the walls of the trench structure. In this case, the lateral dimension of the spacers 11 in a direction x parallel to the wafer surface is chosen such that a first sublithographic dimension SL is formed in a region between the first spacers 11 situated on mutually opposite walls in at least one direction x parallel to the wafer surface (FIG. 4C). The second insulator layer 22 is then etched using the first spacers 11 as far as the connecting contact 5 for the purpose of forming a second passage hole 23 having a form that is for example rectangular or a form that is for example round in plan view, which passage hole, for its part, has at least one sublithographic dimension SL in at least one direction (FIG. 4D). A layer (not specifically illustrated) made of an electrically conductive material is thereupon deposited at least over the second passage hole 23 and is partially etched back in the second passage hole 23 in order thereby to form a first contact electrode 13. In this case, the material of the first contact electrode 13 is chosen such that the latter acts as a heating electrode. A layer (not specifically illustrated) made of a resistance change material is then deposited at least over the second passage hole 23 and is partially etched back in the second passage hole 23, so that a resistance change material zone 14 remains above the heating electrode 13. Afterward, a layer (not specifically illustrated) made of an electrically conductive material is deposited at least on the resistance change material for the purpose of forming a second contact electrode 15 and is removed outside the trench structure 8 by chemical mechanical polishing (FIG. 4E).

Reference will now be made to FIG. 5, which schematically illustrates a variant with respect to the second embodiment of the method according to the invention in the sequence of FIGS. 4A to 4E. In order to avoid unnecessary repetition, only the differences with respect to the method shown therein are explained and otherwise reference is made thereto.

In this embodiment, after depositing the layer made of an electrically conductive material and partially etching back this layer in the second passage hole 23 for the purpose of forming the first contact electrode 13 and after depositing the resistance change material at least over the second passage hole 23 (see FIG. 4E), the first spacers 11 and the resistance change material 14 situated between the first spacers 11 are removed by etching, by way of example, as a result of which a trench structure is formed. Afterward, a second layer (not specifically illustrated) made of a spacer material, which is intended to serve as an etching mask and may accordingly comprise SiN, by way of example, is deposited at least over the first passage hole 21 and is etched back anisotropically until the resistance change material 14 is uncovered in a direction y perpendicular to the wafer surface, second spacers 24 remaining on the walls of the first passage hole 21 or the trench structure formed. In this embodiment, the second spacers 24 situated on mutually opposite walls delimit a region which forms, in at least one direction x parallel to the wafer surface, a second sublithographic dimension, which is advantageously different from the first sublithographic dimension, which may be achieved in a simple manner by virtue of the layer thickness of the second deposited spacer material layer being different from the layer thickness of the first deposited spacer material layer. A second contact electrode 15 made of an electrically conductive material is subsequently formed.

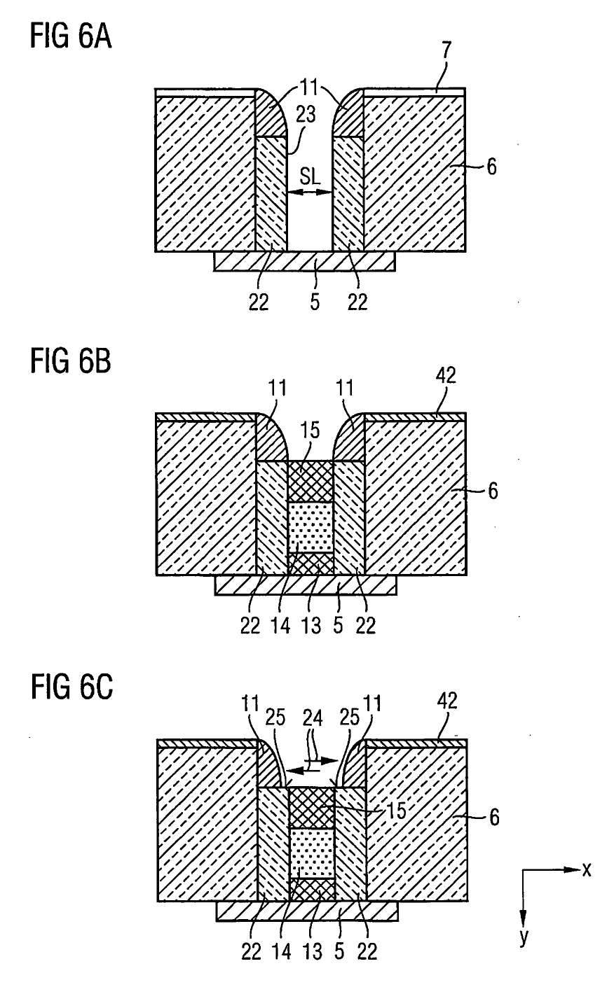

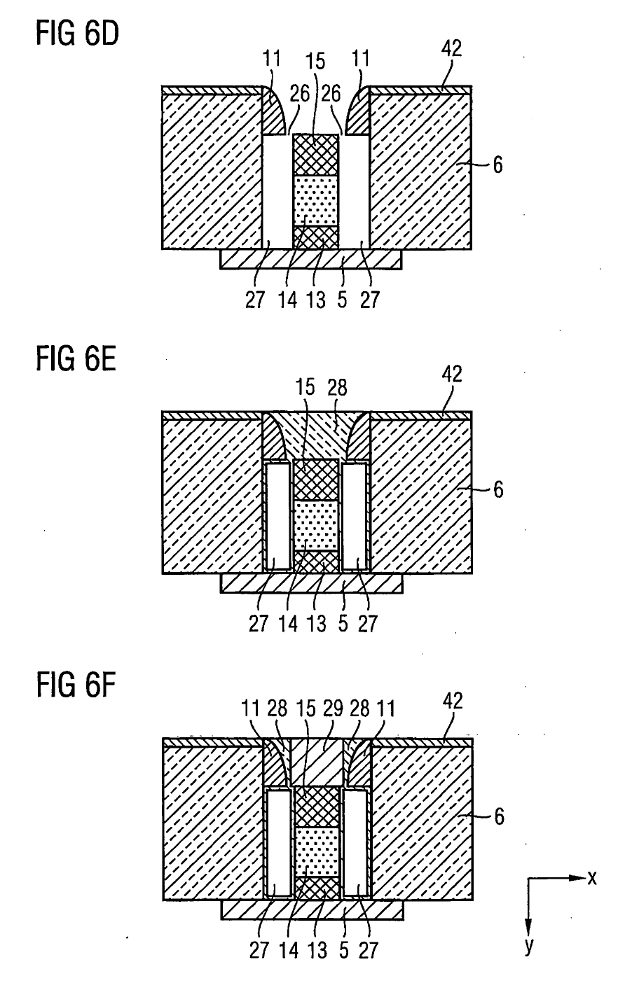

Reference will now be made to the sequence of FIGS. 6A to 6F, which schematically illustrate a further variant with respect to the second embodiment of the method according to the invention in the sequence of FIGS. 4A to 4E. In order to avoid unnecessary repetition, only the differences with respect to the method shown therein are explained and otherwise reference is made thereto. In this case, proceeding from a method stage which corresponds to FIG. 4D and is shown in FIG. 6A, after forming the contact structure, comprising first contact electrode 13, resistance change material 14 and second contact electrode 15, firstly the second contact electrode 15 is partially etched back in the region between the first spacers 11 (FIG. 6B). Afterward, the spacers 11 are partially etched back isotropically in the direction of the arrows 24 for the purpose of increasing the distance between the spacers 11 situated on opposite walls in a direction x parallel to the wafer surface (FIG. 6C), a surface 25 of the second dielectric 22 being partially uncovered. This is followed by selectively isotropically etching the second dielectric material in a direction y perpendicular to the wafer surface, which may be effected wet-chemically, by way of example. In this case, the etching attack takes place on the partially uncovered surface 25 of the second dielectric material 22, the second dielectric material 22 being completely removed to form a cavity 27. As a result of this, the sublithographic contact structure constructed from a layer stack is uncovered at its side walls, a gap 26 arising between the layer stack of the sublithographic contact structure, in particular the second contact electrode 15, and the first spacers 11 (FIG. 6D). A third insulator layer 28 made of a third dielectric material is then deposited conformally at least in the region of the trench structure, which has the effect that the region laterally with respect to the layer stack of the sublithographic contact structure is filled with the third dielectric material until the gap 26 between the second contact electrode 15 and the first spacers 11 has grown over, the cavity 27 remaining. This is followed by forming an electrical connecting contact 29 made of an electrically conductive material for the purpose of making electrical contact with the second contact electrode 15 in a conventional manner.

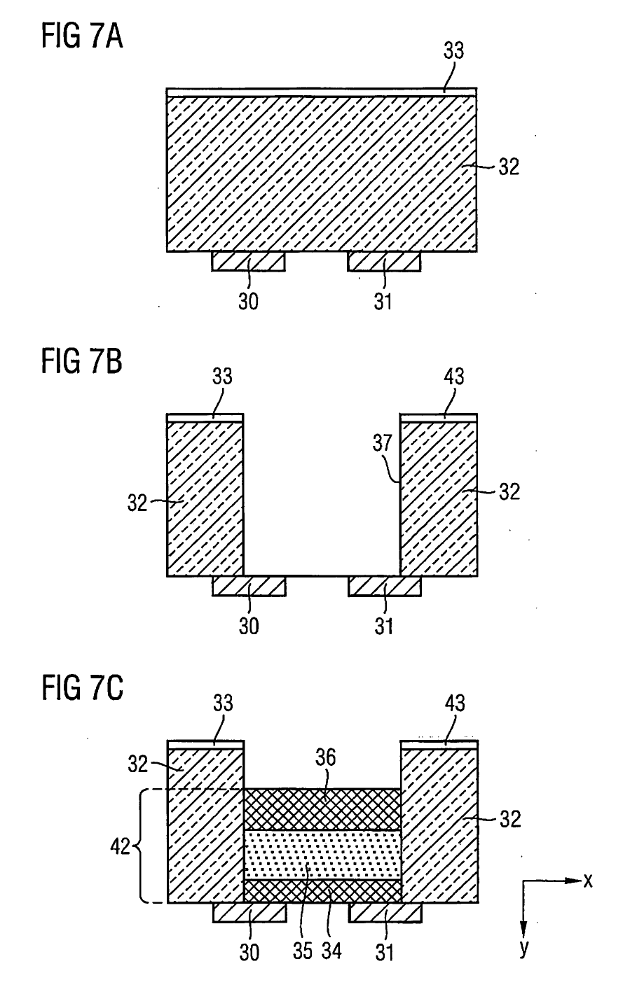

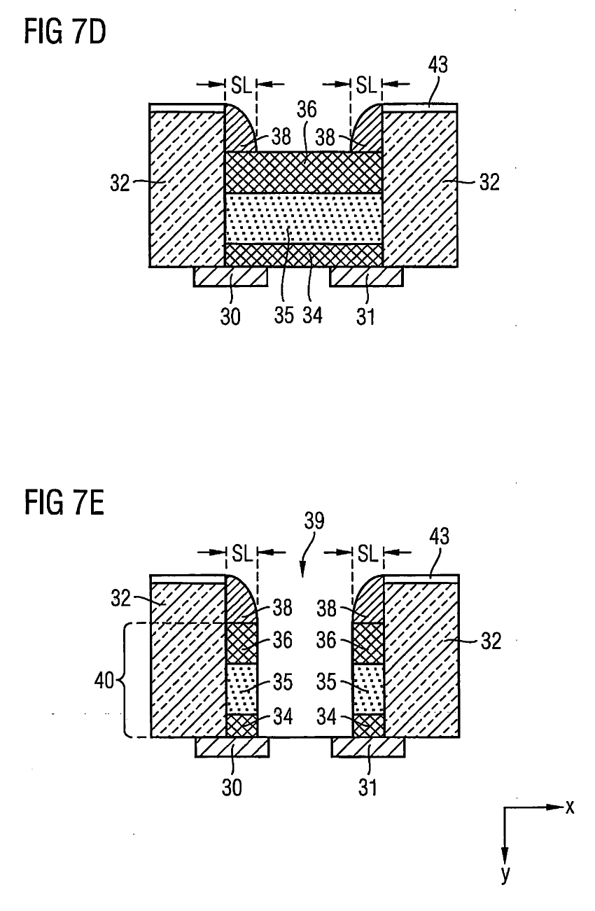

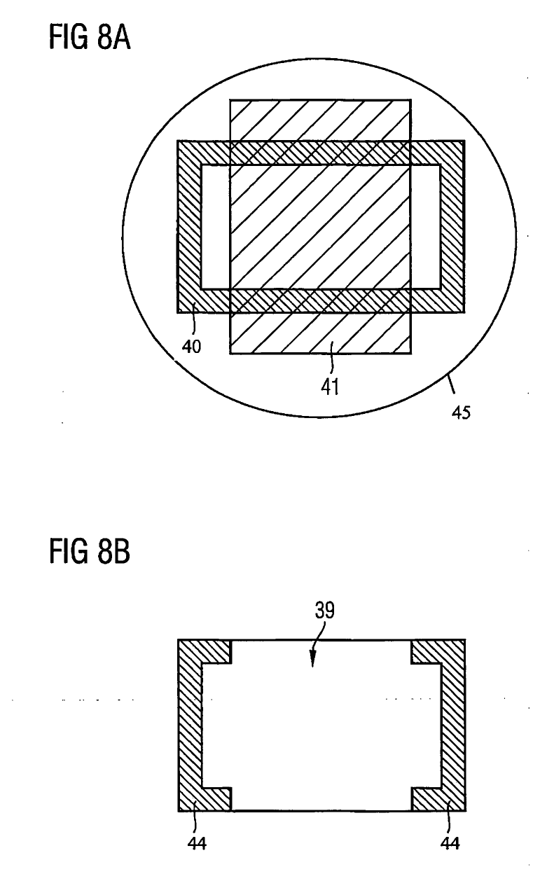

Reference shall now be made to the sequence of FIGS. 7A to 7E, and also FIGS. 8A and 8B, which schematically illustrate an embodiment in accordance with the second aspect of a method according to the invention for simultaneously fabricating a plurality of sublithographic contact structures.

Accordingly, provision is firstly made of a front-end-of-line (FEOL) finished processed semiconductor wafer (not specifically illustrated) with at least two electrical connecting contacts 30, 31 each connected to an active structure on one of its two opposite surfaces. An insulator layer 32 made of a dielectric material is thereupon deposited on the semiconductor wafer at least partially over the connecting contacts 30, 31, followed by the deposition of an etching stop layer 33 (FIG. 7A). The etching stop layer 33 is subsequently patterned in a customary manner to form an etching mask 43. Using this etching mask 43, the dielectric 32 is subsequently etched as far as the first connecting contacts 30, 31 for the purpose of forming a first passage hole 37 (FIG. 7B). A layer made of an electrically conductive material is then deposited and partially etched back in order to form a first contact electrode 34. A layer made of a resistance change material is furthermore deposited and partially etched back in the first passage hole 37 in order to form a resistance change material zone 35. Next, a layer made of an electrically conductive material is deposited and is partially etched back in the first passage hole 37 for the purpose of forming a second contact electrode 36. A stack structure 42, comprising the resistance change material 35 and the two contact electrodes 34, 36, is produced by means of the above steps. A layer made of a spacer material is then deposited, which is intended to serve as an etching mask and may accordingly comprise SiN, by way of example, and is subsequently etched back anisotropically in the passage hole in a direction y essentially perpendicular to the wafer surface until the second contact electrode 36 is uncovered, first spacers 38 remaining on the walls of the first passage hole 37, and the first spacers 38 having a sublithographic dimension SL in at least one direction x parallel to the wafer surface. Afterward, the stack structure 42, comprising the resistance change material 35 and the two contact electrodes 34, 36, is etched as far as the connecting contacts 30, 31 for the purpose of forming a second passage hole 39 and separating the sublithographic contact structures 40, the first spacers 38 being used as an etching mask. In the plan view of FIGS. 8A and 8B it can be discerned how, by subsequent formation of a further etching mask 45 with an etching opening 41 which enables the etching removal and which crosses the stack structure 40 in a central region, and subsequent etching with the aid of the etching mask 45, the stack structure 40 is separated to form two mutually separate sublithographic contact structure sections 44.

Merely for the sake of completeness, it should be mentioned that after the fabrication of the sublithographic contact structure in accordance with the methods of the invention, it is possible to carry out further processes of a back-end-of-line processing for producing further structures, such as insulator layers and metal wiring planes.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for fabricating a sublithographic contact structure in a memory cell in a semiconductor component comprising:
forming a trench structure having first spacers on walls of the trench structure, a first sublithographic dimension (SL) being formed in a region between the first spacers situated on mutually opposite walls in at least one direction (x) parallel to a wafer surface;
etching the insulator layer in a region between the first spacers situated on mutually opposite walls for forming a first passage hole, the first spacers being used as an etching mask;
depositing a layer made of an electrically conductive material at least over the first passage hole and partially etching back the layer made of the electrically conductive material in the first passage hole forming a first contact electrode; and
depositing a layer made of a resistance change material over the first passage hole and partially etching back the resistance change material in the first passage hole forming a resistance change material zone.

2. The method of claim 1, comprising:
depositing a layer made of an electrically conductive material on the resistance change material zone for forming a second contact electrode.

3. The method of claim 1, wherein forming the trench structure comprises:
depositing an etching stop layer on a first insulator layer;
patterning the etching stop forming an etching mask; and
partially etching the first insulator layer with the aid of the etching mask for forming a trench structure.

4. The method as claimed in claim 1, wherein forming the trench structure comprises:
depositing an etching stop layer on a first insulator layer;
patterning the etching stop layer for forming an etching mask;
etching the first insulator layer as far as a connecting contact with the aid of the etching mask for forming a first passage hole; and
depositing a second insulator layer made of a second dielectric material, which is different from the first dielectric material of the first insulator layer, and partially etching back the second insulator layer in the first passage hole for the purpose of forming the trench structure.

5. The method as claimed in claim 4, the thermal conductivity of the second dielectric material being lower than the thermal conductivity of the first dielectric material.

6. A method for fabricating a sublithographic contact structure in a memory cell in a semiconductor component comprising:
providing a front-end-of-line (FEOL) finished processed semiconductor wafer with at least one electrical connecting contact connected to an active structure on one of its two opposite surfaces;
depositing a first insulator layer made of a first dielectric material on the semiconductor wafer at least over the electrical connecting contact;
forming a trench structure with a bottom and walls essentially perpendicular to the wafer surface in the first insulator layer at least partly over the electrical connecting contact;
depositing a first layer made of a dielectric spacer material at least over the trench structure and anisotropically etching back the spacer material layer in a direction essentially perpendicular to the wafer surface as far as the bottom of the trench structure in such a way that first spacers remain on the walls of the trench structure, a first sublithographic dimension (SL) being formed in the region between the first spacers situated on mutually opposite walls in at least one direction (x) parallel to the wafer surface;
etching the insulator layer in the region between the first spacers situated on mutually opposite walls as far as the connecting contact for the purpose of forming a first passage hole, the first spacers being used as an etching mask;
depositing a layer made of an electrically conductive material at least over the first passage hole and partially etching back the layer made of the electrically conductive material in the first passage hole for the purpose of forming a first contact electrode;
depositing a layer made of a resistance change material over the first passage hole and partially etching back the resistance change material in the first passage hole for the purpose of forming a resistance change material zone; and
depositing a layer made of an electrically conductive material on the resistance change material zone for the purpose of forming a second contact electrode.

7. The method as claimed in claim 6, wherein forming the trench structure comprises:
depositing an etching stop layer on the first insulator layer;
patterning the etching stop layer for the purpose of forming an etching mask;
partially etching the first insulator layer with the aid of the etching mask for the purpose of forming a trench structure.

8. The method as claimed in claim 6, wherein forming the trench structure comprises:
depositing an etching stop layer on the first insulator layer;
patterning the etching stop layer for the purpose of forming an etching mask;
etching the first insulator layer as far as the connecting contact with the aid of the etching mask for the purpose of forming a first passage hole; and
depositing a second insulator layer made of a second dielectric material, which is different from the first dielectric material of the first insulator layer, and partially etching back the second insulator layer in the first passage hole for the purpose of forming a trench structure.

9. The method as claimed in claim 8, wherein the thermal conductivity of the second dielectric material being lower than the thermal conductivity of the first dielectric material.

10. A method for fabricating a sublithographic contact structure in a memory cell in a semiconductor component, comprising:
providing a front-end-of-line (FEOL) finished processed semiconductor wafer with at least one electrical connecting contact connected to an active structure on one of its two opposite surfaces;
depositing a first insulator layer made of a first dielectric material on the semiconductor wafer at least over the electrical connecting contact;
forming a trench structure with a bottom and walls essentially perpendicular to the wafer surface in the first insulator layer at least partly over the electrical connecting contact;
depositing a first layer made of a dielectric spacer material at least over the trench structure and anisotropically etching back the spacer material layer in a direction essentially perpendicular to the wafer surface as far as the bottom of the trench structure in such a way that first spacers remain on the walls of the trench structure, a first sublithographic dimension (SL) being formed in the region between the first spacers situated on mutually opposite walls in at least one direction (x) parallel to the wafer surface;
etching the insulator layer in the region between the first spacers situated on mutually opposite walls as far as the connecting contact for the purpose of forming a first passage hole, the first spacers being used as an etching mask;
depositing a layer made of an electrically conductive material at least over the first passage hole and partially etching back the layer made of the electrically conductive material in the first passage hole for the purpose of forming a first contact electrode;
depositing a layer made of a resistance change material over the first passage hole and partially etching back the resistance change material in the first passage hole for the purpose of forming a resistance change material zone;
depositing a layer made of an electrically conductive material on the resistance change material for the purpose of forming a second contact electrode, partially etching back the second contact electrode in the region between the first spacers;
partially isotropically etching back the first spacers on the walls of the trench structure in a direction (x) essentially parallel to the wafer surface for the purpose of increasing the distance between the first spacers situated on opposite walls;
selectively isotropically etching the second dielectric material in a direction (y) essentially perpendicular to the wafer surface;
conformally depositing a third insulator layer made of a third dielectric material at least in the region of the trench structure; and
forming an electrically conductive connection to the second contact electrode in the third insulator layer.

11. The method as claimed in claim 10, wherein forming the trench structure comprises:
depositing an etching stop layer on the first insulator layer;
patterning the etching stop layer for the purpose of forming an etching mask; and
partially etching the first insulator layer with the aid of the etching mask for the purpose of forming a trench structure.

12. The method as claimed in claim 10, the trench structure being formed by the following steps of:
depositing an etching stop layer on the first insulator layer;
patterning the etching stop layer for the purpose of forming an etching mask;
etching the first insulator layer as far as the connecting contact with the aid of the etching mask for the purpose of forming a first passage hole;
depositing a second insulator layer made of a second dielectric material, which is different from the first dielectric material of the first insulator layer, and partially etching back the second insulator layer in the first passage hole for the purpose of forming a trench structure.

13. The method as claimed in claim 12, the thermal conductivity of the second dielectric material being lower than the thermal conductivity of the first dielectric material.

14. A method for fabricating a sublithographic contact structure in a memory cell in a semiconductor component, comprising:
providing a front-end-of-line (FEOL) finished processed semiconductor wafer with at least one electrical connecting contact connected to an active structure on one of its two opposite surfaces;
depositing a first insulator layer made of a first dielectric material on the semiconductor wafer at least over the electrical connecting contact;
forming a trench structure with a bottom and walls essentially perpendicular to the wafer surface in the first insulator layer at least partly over the electrical connecting contact;
depositing a first layer made of a dielectric spacer material at least over the trench structure and anisotropically etching back the spacer material layer in a direction essentially perpendicular to the wafer surface as far as the bottom of the trench structure in such a way that first spacers remain on the walls of the trench structure, a first sublithographic dimension (SL) being formed in the region between the first spacers situated on mutually opposite walls in at least one direction (x) parallel to the wafer surface;
etching the insulator layer in the region between the first spacers situated on mutually opposite walls as far as the connecting contact for the purpose of forming a first passage hole, the first spacers being used as an etching mask;
depositing a layer made of an electrically conductive material at least over the first passage hole and partially etching back the layer made of the electrically conductive material in the first passage hole for the purpose of forming a first contact electrode;
depositing a layer made of a resistance change material over the first passage hole and partially etching back the resistance change material for the purpose of forming a resistance change material zone and removing the first spacers and the resistance change material situated between the latter;
depositing a second layer made of a spacer material at least over the trench structure and anisotropically etching back the spacer material layer in a direction essentially perpendicular to the wafer surface until the resistance change material is uncovered, in such a way that second spacers remain on the walls of the trench structure, a second sublithographic dimension, which is different from the first sublithographic dimension, being formed in the region between the second spacers situated on mutually opposite walls in at least one direction (x) parallel to the wafer surface; and
depositing a layer made of an electrically conductive material on the resistance change material for the purpose of forming a second contact electrode.

15. The method as claimed in claim 14, the second sublithographic dimension being smaller than the first sublithographic dimension.

16. The method as claimed in claim 14, wherein forming the trench structure comprises:
depositing an etching stop layer on the first insulator layer;
patterning the etching stop layer for the purpose of forming an etching mask; and
partially etching the first insulator layer with the aid of the etching mask for the purpose of forming a trench structure.

17. The method as claimed in claim 14, wherein forming the trench structure comprises:
depositing an etching stop layer on the first insulator layer;
patterning the etching stop layer for the purpose of forming an etching mask;
etching the first insulator layer as far as the connecting contact with the aid of the etching mask for the purpose of forming a first passage hole; and
depositing a second insulator layer made of a second dielectric material, which is different from the first dielectric material of the first insulator layer, and partially etching back the second insulator layer in the first passage hole for the purpose of forming a trench structure.

18. The method as claimed in claim 9, the thermal conductivity of the second dielectric material being lower than the thermal conductivity of the first dielectric material.

19. A method for fabricating a sublithographic contact structure in a memory cell in a semiconductor component, which comprises the following steps of:
providing a front-end-of-line (FEOL) finished processed semiconductor wafer with at least one electrical connecting contact connected to an active structure on one of its two opposite surfaces;
depositing a first insulator layer made of a first dielectric material on the semiconductor wafer at least over the electrical connecting contact;
forming a trench structure with a bottom and walls essentially perpendicular to the wafer surface in the first insulator layer at least partly over the electrical connecting contact;
depositing a first layer made of a dielectric spacer material at least over the trench structure and anisotropically etching back the spacer material layer in a direction essentially perpendicular to the wafer surface as far as the bottom of the trench structure in such a way that first spacers remain on the walls of the trench structure, a first sublithographic dimension (SL) being formed in the region between the first spacers situated on mutually opposite walls in at least one direction (x) parallel to the wafer surface;
etching the insulator layer in the region between the first spacers situated on mutually opposite walls as far as the connecting contact for the purpose of forming a first passage hole, the first spacers being used as an etching mask;
depositing a layer made of an electrically conductive material at least over the first passage hole and partially etching back the layer made of the electrically conductive material in the first passage hole for the purpose of forming a first contact electrode;
depositing a layer made of a resistance change material over the first passage hole and partially etching back the resistance change material for the purpose of forming a resistance change material zone and removing the first spacers and the resistance change material situated between the latter;
depositing a second layer made of a spacer material at least over the trench structure and anisotropically etching back the spacer material layer in a direction essentially perpendicular to the wafer surface until the resistance change material is uncovered, in such a way that second spacers remain on the walls of the trench structure, a second sublithographic dimension, which is different from the first sublithographic dimension, being formed in the region between the second spacers situated on mutually opposite walls in at least one direction (x) parallel to the wafer surface;
depositing a layer made of an electrically conductive material on the resistance change material for the purpose of forming a second contact electrode;
partially etching back the contact electrode in the region between the second spacers;
partially isotropically etching back the spacer material on the walls of the trench structure in a direction (x) essentially parallel to the wafer surface for the purpose of increasing the distance between the second spacers situated on opposite walls in a direction (x) parallel to the wafer surface;
selectively isotropically etching the second dielectric material in a direction (y) essentially perpendicular to the wafer surface;
conformally depositing a third insulator layer made of a third dielectric material at least in the region of the trench structure; and
forming an electrically conductive connection to the second contact electrode in the third insulator layer.

20. The method as claimed in claim 19, wherein forming the trench structure comprises:
depositing an etching stop layer on the first insulator layer;
patterning the etching stop layer for the purpose of forming an etching mask; and
partially etching the first insulator layer with the aid of the etching mask for the purpose of forming a trench structure.

21. The method as claimed in claim 19, wherein forming the trench structure comprises:
depositing an etching stop layer on the first insulator layer;
patterning the etching stop layer for the purpose of forming an etching mask;
etching the first insulator layer as far as the connecting contact with the aid of the etching mask for the purpose of forming a first passage hole; and
depositing a second insulator layer made of a second dielectric material, which is different from the first dielectric material of the first insulator layer, and partially etching back the second insulator layer in the first passage hole for the purpose of forming a trench structure.

22. The method as claimed in claim 16, the thermal conductivity of the second dielectric material being lower than the thermal conductivity of the first dielectric material.

23. The method as claimed in claim 1, the trench structure having at least one minimum dimension that can be achieved photolithographically in at least one direction.

24. The method as claimed in claim 1, the sublithographic dimension being less than 50 nm.

25. A method for fabricating sublithographic contact structures in memory cells in a semiconductor component, comprising:
providing a front-end-of-line (FEOL) finished processed semiconductor wafer with at least two electrical connecting contacts each connected to an active structure on one of its two opposite surfaces;
depositing an insulator layer made of a dielectric material on the semiconductor wafer at least partially over the two connecting contacts;
forming an etching mask on the insulator layer;
etching the dielectric as far as the connecting contacts for the purpose of forming a first passage hole;
depositing a layer made of an electrically conductive material and partially etching back the layer made of an electrically conductive material for the purpose of forming a first contact electrode;
depositing a layer made of a resistance change material and partially etching back the resistance change material in the first passage hole for the purpose of forming a resistance change material zone;
depositing a layer made of an electrically conductive material. and partially etching back the electrically conductive material in the first passage hole for the purpose of forming a second contact electrode;
depositing a layer made of a spacer material and anisotropically etching back the spacer material layer in a direction (y) essentially perpendicular to the wafer surface in the first passage hole until the second contact electrode is uncovered, in such a way that first spacers remain on the walls of the first passage hole and the first spacers have a sublithographic dimension (SL) in at least one direction (x) parallel to the wafer surface;
etching the second contact electrode, the resistance change material zone and the first contact electrode as far as the connecting contacts, the first spacers being used as an etching mask, whereby a sublithographic contact structure is formed; and
forming an etching mask at least over the sublithographic contact structure and etching the sublithographic contact structure for the purpose of producing two sublithographic contact structure sections.

26. The method as claimed in claim 25, the first passage hole having at least one minimum dimension that can be achieved photolithographically in at least one direction.
